(19) United States
(12) Patent Application Publication
(10) Pub. No.: US 2025/0020694 A1
(43) Pub. Date: Jan. 16, 2025

(54) PLATFORM TO STREAM, VIEW, ANALYZE AND COLLABORATE ON TEST AND MEASUREMENT WAVEFORM DATA

(71) Applicant: Tektronix, Inc., Beaverton, OR (US)

(72) Inventors: Thomas Buida, Nashville, TN (US); Adam M. Reeves, Nashville, TN (US); Gaurav Marmat, Alpharetta, GA (US); Broc Borntrager, Nashville, TN (US)

(21) Appl. No.: 18/767,826

(22) Filed: Jul. 9, 2024

Related U.S. Application Data
(60) Provisional application No. 63/513,539, filed on Jul. 13, 2023.

(51) Int. Cl. G01R 13/02; G06F 3/0482; H04L 67/10

(52) U.S. Cl. CPC G01R 13/02; G06F 3/0482; H04L 67/10

(57) ABSTRACT

Methods and systems provide access to acquired waveforms from a test and measurement instrument for multiple users. A method includes storing acquired waveforms from the instrument in a cloud-based platform and rendering, on a display of a first remote user device, a timeline illustrating in chronological order each acquired waveform from the instrument in response to the acquired waveform being stored in the cloud-based platform. An acquired waveform on the timeline is selected for viewing and at least one user-selectable feature view configured to display corresponding characteristics of the selected acquired waveform. A file from the cloud-based platform is received including data for the at least one user-selectable feature view and the configurable viewing window including the at least one user-selectable feature view using the file received is rendered on the first remote user device. The configurable viewing window may be shared with at least one other remote user device.

### PRIORITY

This disclosure is a non-provisional of and claims benefit from U.S. Provisional Application No. 63/513,539, titled “AN ALL-IN-ONE PLATFORM TO STREAM, VIEW, ANALYZE AND COLLABORATE ON TEST AND MEASUREMENT WAVEFORM DATA,” filed on Jul. 13, 2023, the disclosure of which is incorporated herein by reference in its entirety.

### TECHNICAL FIELD

This disclosure relates to test and measurement systems, and more particularly to a cloud-based platform providing a user interface enabling collaboration by users in streaming, viewing, and analyzing acquired waveforms from a test and measurement instrument.

### BACKGROUND

Test and measurement instruments, such as oscilloscopes, acquire waveforms of one or more signals under test. These waveforms may be very large in size and include gigabytes of data, making the sharing of such waveforms difficult among multiple users interested in viewing and analyzing the waveforms. Prior approaches to sharing acquired waveforms included taking a screenshot of the waveform on a user's computer and sending the screenshot to others to avoid the time and bandwidth limitations of sending the actual data of the acquired waveform. While enabling some collaboration, this approach has limited utility, with analysis being greatly restricted for everyone who does not have access to the acquired waveform.

Sharing acquired waveforms through Internet-connected cloud platforms has somewhat improved multi-group collaboration. The cloud platform includes components for storing, managing, and processing acquired waveforms from the test and measurement instrument. The acquired waveforms from a test and measurement instrument may also be referred to as “test and measurement data” or “measurement data” in the present description. The cloud platform enables multiple users to access the measurement data and to utilize it for their required purposes. While such a cloud platform provides multiple users access to the measurement data, collaboration may still be difficult as different groups of users of the measurement data may have different needs, such as different views illustrating different characteristics of the measurement data. For example, an embedded software engineer may be interested in protocol-related aspects of the measurement data and desire a view showing the decoded measurement data according to the protocol being utilized. In contrast, a radio frequency (RF) engineer may be interested in a view of the acquired waveform showing RF-related transformations such as a view showing the frequency spectrum of the waveform.

Manufacturers of test and measurement instruments have provided cloud platforms to provide the advantage of easily distributing acquired waveforms from test and measurement instruments like oscilloscopes to multiple users for viewing and analysis. Providing acquired waveforms through cloud platforms enables collaboration of multiple users. Accessing the multi-gigabyte files forming the acquired waveforms may, however, be a time-consuming process, which results in a poor user experience. To alleviate these issues, some cloud platforms include user interfaces in the form of web browser-based interfaces that allow a user to access these multi-gigabyte files. While these web browser-based interfaces have overcome issues related to memory management and the loading and viewing of the desired multi-gigabyte files with good performance, the collaborative functionality of such solutions is still limited. Collaborative functionality providing the ability to create specific views showing particular desired measurements for acquired waveforms is highly desirable for cross functional engineering teams, which will typically have sub-teams of users interested in different measurements and views of the acquired waveforms to accomplish their respective sub-team objectives. Accordingly, there is a need for methods and systems that improve the ability of groups of users to collaboratively access acquired waveforms from test and measurement instruments.

### BRIEF DESCRIPTION OF THE DRAWINGS

FIG. 1 shows a test and measurement system including a number of remote user devices having respective user interfaces enabling collaboration among users in accessing test and measurement data from a test and measurement instrument stored that is stored over a network in a cloud-based platform in accordance with embodiments of the disclosure.

FIG. 2 is an example of a display window rendered by a presentation layer of the user interfaces of FIG. 1 in accordance with embodiments of the disclosure.

FIG. 3 is another example of a display window rendered by the replacement layer of the user interfaces of FIG. 1 in accordance with embodiments of the disclosure.

FIG. 4 is a flowchart illustrating a display process executed through the replacement layer and display window of FIG. 2 in accordance with embodiments of the disclosure.

### DETAILED DESCRIPTION

Embodiments according to the present disclosure relate to the technical field of test and measurement instruments such as oscilloscopes, and disclose methods and systems that improve the ability for multiple users to collaborate on accessing and analyzing test and measurement data generated by an oscilloscope during testing of a device under test. Embodiments of the disclosure generally include cloud-based storage and processing of acquired waveforms generated by such a test and measurement instrument in combination with remote user devices that may access the acquired waveforms for analysis. The remote user devices enable users to perform desired data transformations of the acquired waveforms to display, on the remote user devices, desired characteristics of the acquired waveforms, and allow sharing with, and collaboration amongst, multiple users having access to the acquired waveforms through respective remote user devices.

In embodiments of the disclosure, each remote user device includes one or more processors configured to execute instructions to cause the processors to render a user interface on a display of the remote user device. The user interface includes a presentation layer to display a timeline illustrating, in chronological order, each acquired waveform from the instrument in response to the acquired waveform being stored in the cloud-based platform. The replacement layer receives user input to select a desired one of the acquired waveforms illustrated on the timeline for viewing on the display of the first remote user device. The presentation layer may simultaneously display multiple configurable viewing windows, each configurable viewing window including at least one user-selectable feature view to display corresponding characteristics of the selected acquired waveform. The presentation layer may receive user input to select one of the configurable viewing windows to be shared with other remote user devices, and a user may share the selected configurable viewing window with the other remote users to enable them to view the selected configurable viewing window.

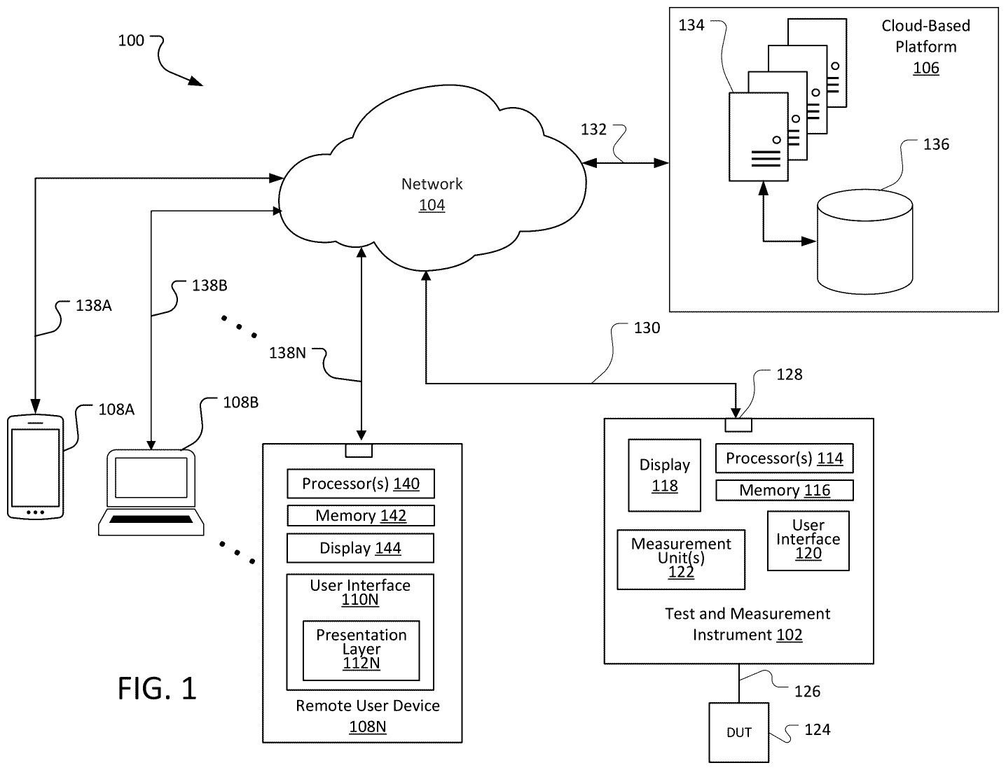

FIG. 1 shows a test and measurement system 100 including a test and measurement instrument, referred to as instrument 102, connected through a network 104 to a cloud-based platform 106. The test and measurement system 100 also includes several remote user devices 108A-108N each having respective user interfaces 110A-110N in accordance with embodiments of the disclosure. Although internal functional components of the remote user device 108N are shown in detail in FIG. 1 to simplify the figure, each of the other remote user devices 108A-108N includes the corresponding user interface 110A-110N. Further, each of the user interfaces 110A-N includes a respective presentation layer 112A-N that enables collaboration among users in accessing measurement data from the instrument 102 that has been stored in the cloud-based platform 106. The measurement data generated by the instrument 102 is communicated over the network 104 and stored in the cloud-based platform 106 for access by the remote user devices 108A-N. Accessing the measurement data stored in the cloud-based platform 106 includes streaming, viewing, and analyzing the data using the presentation layers 112A-N of user interfaces 110A-N of the remote user devices 108A-N to configure and share views including various data transformations of the measurement data from the instrument 102, as described in more detail below.

In the test and measurement system 100 of FIG. 1, the instrument 102 includes one or more processors 114, a memory 116, a display 118, and a user interface 120, which may exist as part of a touch-screen display or take the form of control knobs and other user input devices. The one or more main processors 114 are configured to execute instructions from memory 116 to implement any methods and associated steps defined by such instructions to control the overall operation of the instrument 102. One or more measurement units 122 in the instrument 102 perform the main functions of measuring parameters and other qualities of signals from a device under test (DUT) 124 being tested or analyzed by the test and measurement system 100. Some measurements performed by the one or more measurement units 122 include measuring voltage, current, and power of input signals in the time domain, as well as measuring characteristics of the signals in the frequency domain. The one or more measurement units 122 represent any components for performing any measurements that are typically performed on test and measurement instruments. The instrument 102 is coupled to the DUT 124 through a connection 126, such one or more cables or other suitable types of electrical connections.

Testing the DUT 124 by the instrument 102 generates acquired waveforms for upload through the network 104 to the cloud-based platform 106. For these uploads, a network port 128 of the instrument 102 is coupled through a connection 130 to the network 104 and further through a network connection 132 to the cloud-based platform 106. In this way, the network port 128 allows the instrument 102 to upload, over the network 104, acquired waveforms to the cloud-based platform 106 for storage and subsequent accessing by the remote user devices 108A-N.

The cloud-based platform 106 is coupled through the network connection 132 and through the network 104 to the instrument 102. The cloud-based platform 106 may include one or more servers 134, each of which may have one or more processors (not shown) and dedicated memory (not shown), as well as other server components also not expressly illustrated in FIG. 1. In some examples, the cloud-based platform 106 includes a common memory 136 that may be shared by the one or more servers 134, which enables the cloud-based platform 106 to store the original acquired waveforms from the instrument 102 in native format. The “native format” of the acquired waveforms from the instrument 102 means the original format of a file corresponding to each acquired waveform as generated by the instrument 102. These native format files may be very large, as previously discussed, being up to multi-gigabytes in size. The common memory 136 of the cloud-based platform 106 typically has a large capacity sufficient to store many acquired waveforms in native format generated by the instrument 102. In this way, the common memory 136 enables storage of numerous acquired waveforms from the instrument 102—many more than could be stored in the memory 116 of the instrument 102.

In embodiments of the test and measurement system 100, the cloud-based platform 106 stores not only native format files of the acquired waveforms or measurement data from the instrument 102, but also performs additional processing of the measurement data, including transformations of the measurement data, which enables the presentation layers 112A-N of user interfaces 110A-N to improve collaboration of users in analyzing the measurement data, as described in more detail below. In embodiments, the cloud-based platform 106 attaches measurements to the acquired waveform files or measurement data from the instrument 102 as metadata to create a library of measurements, classifications, decodes, and other algorithms, and store them in the common memory 136. The cloud-based platform 106 generates this metadata whenever newly acquired waveforms are stored in the cloud-based platform. The “measurements” generated by the cloud-based platform 106 are any measurement, query, search, filter, classification, decode, etc., which is performed on or run against the newly acquired waveforms or measurement data. The cloud-based platform 106 may, in some embodiments, also implement methods to automatically crawl historical measurement data already stored in the platform 106, and update the memory 136 as new measurements are added. Processing the acquired waveforms or measurement data in the cloud-based platform 106 to produce metadata in accordance with embodiments of the disclosure are described in more detail in U.S. Patent Application Publication No. 2022/0252647A1, entitled METHOD OF GENERATING METADATA FROM ACQUIRED SIGNALS FOR SEARCH, FILTERING, AND MACHINE LEARNING INPUTS, filed on Feb. 4, 2022, the disclosure of which is incorporated herein by reference in its entirety.

In embodiments of the test and measurement system 100, the cloud-based platform 106 further operates to transfer or upload not only the acquired waveforms in native format from the instrument 102, but also to compress and/or segment these acquired waveforms to generate one or more compressed and/or segmented versions of the acquired waveforms that are stored on the cloud-based platform 106. The term “compression” in this context means any method of reducing a size of the file corresponding to the acquired waveform or measurement data from the instrument 102. Alternatively, or additionally, the cloud-based platform 106 may segment each original acquired waveform in native format into smaller segments, and store each of the smaller segments at an original resolution of the acquired waveform.

In operation, the cloud-based platform 106 may transmit a segment of the original acquired waveform in response to user inputs to the presentation layer 112A-N of the corresponding remote user device 108A-N to allow a user to zoom in on a desired portion of the acquired waveform, which may be considered a “zoomed view” of the desired portion of the acquired waveform. The cloud-based platform 106 may store segments of the acquired waveform in their original native format (i.e., uncompressed form) to allow for such zooming by users through the presentation layers 112A-N. In this way, presentation layers 112A-N of user interfaces 110A-N in remote user devices 108A-N may use the compressed and/or segmented versions of the acquired waveforms to enable viewing and collaboration by users in analyzing the acquired waveforms, as described in more detail below. Each of the remote user devices 108A-N may, for example, be a laptop computer, a tablet computer, a smart phone, or any other suitable type of electronic device on which the user interface 110A-N may be displayed and controlled by a user of the remote user device.

The operation of the cloud-based platform 106 to generate one or more compressed and segmented versions of the acquired waveforms from a measurement instrument, such as instrument 102 of FIG. 1, is described in more detail in U.S. Patent Application Publication No. 2022/0163566A1, entitled SYSTEM AND METHOD FOR HIGH PERFORMANCE DISTRIBUTION OF LARGE WAVEFORM CAPTURES TO MULTIPLE VIEWERS, filed on Nov. 19, 2021, the disclosure of which is incorporated herein by reference in its entirety. Using these compressed versions of the acquired waveforms on the cloud-based platform 106 in relation to the operation of the presentation layers 112A-N and user interfaces 110A-N of the remote user devices 108A-N is described in more detail below.

Once the acquired waveforms from the instrument 102 have been transferred or uploaded to the cloud-based platform 106, multiple users may, through configuration of the remote user devices 108A-N, simultaneously, at least partially simultaneously, or sequentially, access the compressed and/or segmented versions of the acquired waveforms, as well as the native format of the acquired waveforms, to work with and analyze different aspects of the acquired waveform. The remote user devices 108A-N are coupled through network connections 138A-N and the network 104 to the cloud-based platform 106. As described in more detail below, the presentation layers 112A-N of the user interfaces 110A-N of the remote user devices 108A-N may be configured to access, display, and share desired versions of the acquired waveforms stored on the cloud-based platform 106, enabling improved collaboration among users.

Example components of the remote user device 108N are described in more detail herein. As mentioned above, although the remote user device 108N is the only of the remote user devices illustrated in FIG. 1 that illustrates functions of internal components, each of the other user devices 108A-108N includes similar components and corresponding user interfaces 110A-110N and presentation layers 112A-112N. The remote user device 108N includes one or more processors 140, a memory 142, a display 144, and the user interface 110N. The one or more processors 140 are configured to execute instructions from memory 142 to implement methods defined by such instructions and thereby control the overall operation of the remote user device 108N, including operation of the presentation layer 112N to enable users to access desired versions of acquired waveforms stored on the cloud-based platform 106. The display 144 may be any suitable type of digital screen such as an LED display or a LCD, or any other suitable type of display. The display 144 renders or displays windows generated by the presentation layer 112N of the user interface 110N for viewing by a user of the remote user device 108N. The user interface 110N may include a keyboard, mouse, touchscreen, or any other suitable controls employable by a user to interact with the remote user device 108N.

In the test and measurement system 100, the network 104 may include a closed network, meaning a network available only to users of a particular company, building, or private network, or may include an open network, for example including the Internet, may be a virtual private network, and may be other suitable types of network architectures as well. The network connections 130, 132, and 138A-N between components of the test and measurement system 100 may be any suitable type of wired or wireless network, including near-field communications (NFC) connections, infrared (IR) connection, Bluetooth® connections, Wi-Fi connections, Ethernet connections, and so on.

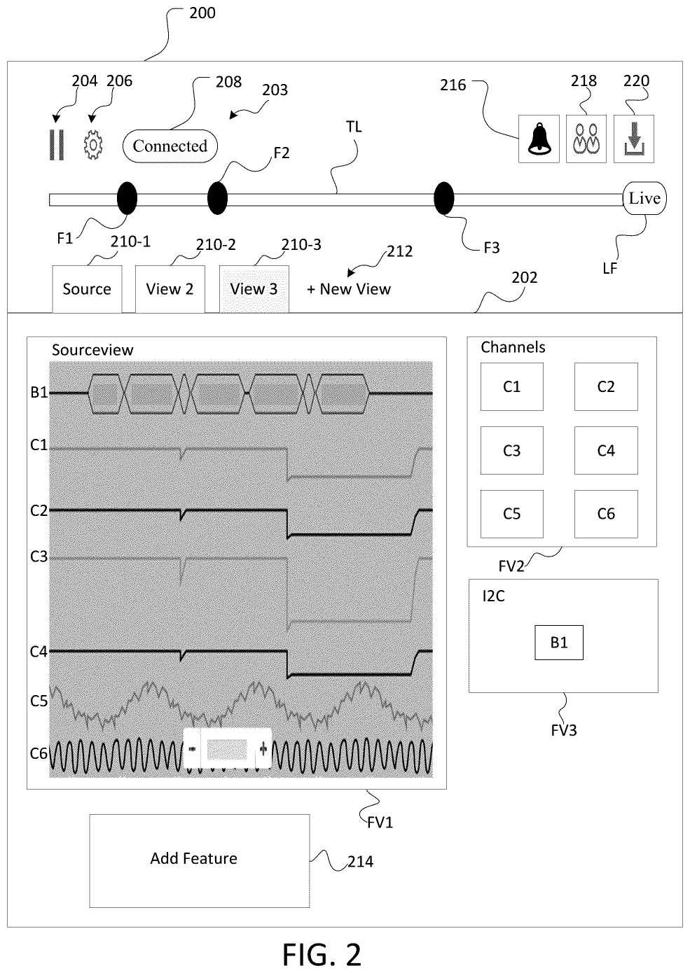

FIG. 2 illustrates an example of a display window 200 rendered by the presentation layers 112A-N of user interfaces 110A-N in the remote user devices 108A-N in the test and measurement system 100 of FIG. 1 in accordance with embodiments of the disclosure. As described above, the test and measurement system 100 is a cloud-based system. In operation, after one of the remote user devices 108A-N makes a request, the one or more servers 134 of the cloud-based platform 106 retrieves data corresponding to the request from the common memory 136. After the requested data has been retrieved, the cloud-based platform 106 sends the requested data to the requesting remote user device through the network connection 132 and network 104 (FIG. 1), where the requested data is received by a client program, such as a browser executing on the remote user devices 108A-N. The client program implements the user interface 110A-N and presentation layers 112A-N on the remote user devices 108A-N.

The user of one of the remote user devices 108A-N generally interacts with the user interface 110A-N of the remote user device 108A-N to make data selections or to generate other user inputs. These user inputs are then communicated over the network connections 138A-N, network 104 and network connection 132 to the one or more servers 134 executing on the cloud-based platform 106. In response to the user inputs, the one or more servers 134 selects or generates an updated file corresponding to the display window selected by the user, and communicates this file to the remote user device 108A-N for rendering on the remote user device 108A-N. The architecture of the remote user devices 108A-N and one or more servers 134 of the cloud-based platform 106 is client-server architecture, and operation between of the client programs executing on the remote user devices 108A-N and the one or more servers 134 executing on the cloud-based platform 106 is understood by those skilled in the art, and is not described in detail herein.

Through the display window 200 and user interface 110N, the user is able to select desired ones of the acquired waveforms generated by the instrument 102 and to configure views showing desired characteristics or features of the acquired waveforms for viewing and sharing with other users, as described in more detail. The example display window 200 of FIG. 2 includes a timeline TL illustrating, in chronological order from left to right, each acquired waveform that was previously generated by the instrument 102 and stored in the cloud-based platform 106.

In the example embodiment of FIG. 1, each acquired waveform is represented as an icon along the timeline TL, with each of these icons representing a corresponding acquired waveform that may also be referred to as a frame F in the present description. Three frames F1-F3 on the timeline TL are shown in the example of FIG. 2. Spacing among frames F1-F3 on the timeline TL indicates when each frame was acquired relative to the other frames. For example, frame F2 precedes F3. To select one of the frames F1-F3, a user of the remote user device 108N containing the user interface 110N and presentation layer 112N that is presenting or rendering the display window 200 utilizes a user input device (not shown). The user input device is part of the user interface and may be, for example, a computer mouse or a touch screen. The selected one of the frames F1-F3 is then displayed in a configurable viewing window 202. The specific manner in which data of the selected frame F1-F3 is presented in the configurable viewing window 202 may vary and is configurable by the user, as described in more detail below.

In the embodiment of FIG. 2, the timeline TL further includes an icon representing a live stream or live frame LF. The live frame LF represents, in real time, the measurement data that is currently being acquired from the DUT 124 (FIG. 1) by the instrument 102. A user may select the live frame icon LF to view in the configurable viewing window 202 the current measurement data being acquired by the instrument 102 during acquisition of live acquisition waveform or live frame currently being acquired by the instrument 102. There will of course be some latency between the measurement data currently being acquired by the instrument 102, namely the measurement data of the live frame LF, and the display of this measurement data on the corresponding remote user device 108A-N. Thus, the term “real time” as used to describe the measurement data of the live frame LF includes this latency. The frames F1-F3, LF on the timeline TL represent continuous measurement data generated or acquired by the instrument 102. The acquired waveforms or frames of the measurement data acquired by the instrument 102 are defined by configuring operational parameters or triggers on the instrument 102. The instrument 102 may be configured directly on the instrument 102 but configuring the instrument 102 may also be performed remotely on the remote user device 108N through the presentation layer 112N. More specifically, the presentation layer 112N renders an instrument control panel 203 as part of the configurable viewing window 202. The instrument control panel 203 includes a pause icon 204 which, when selected by the user, causes the instrument 102 to pause capturing measurement data from the DUT 124 (FIG. 1) and thereby pause the capturing of additional acquired waveforms or frames F. A configuration icon 206 in the instrument control panel 203 allows a user to configure and control the instrument 102 by configuring operational parameters of the instrument 102. For example, where the instrument 102 is an oscilloscope, the user may select the configuration icon 206 to configure sample rate, record length for each acquired waveform or frame F, triggers, and horizontal and vertical settings for acquired measurement data, with subsequent acquired waveforms or frames then being updated to include the configured operational parameters. Selecting the configuration icon 206 enables the user to configure desired operational parameters of the instrument 102. In the example embodiment of FIG. 2, the instrument control panel 203 further includes a connection icon 208 indicating whether instrument 102 is currently connected to the cloud-based platform 106 (FIG. 1). The connection icon 208 indicates “Connected” as shown in FIG. 2 when the instrument 102 is connected and displays another descriptor, such as “Not Connected,” when the instrument 102 is not connected to the cloud-based platform 106.

Returning now to the configurable viewing window 202 in the display window 200 of FIG. 2, once a user has selected the desired one of the frames F1-F3 or the live frame LF on the timeline TL, the user may then configure the configurable viewing window 202 to illustrate desired characteristics of the selected frame for review and analysis, and may share the viewing window with other users, as described in more detail herein. The configurable viewing window 202 may include multiple individual configurable viewing windows created by the user. In the example display window 200 of FIG. 2, multiple individual configurable viewing windows 210-1, 210-2 and 210-3 have been created by the user. A first individual configurable viewing window 210-1 is labelled “Source” and is an initial default viewing window that is presented in the display window 200 when the display window 200 is initially accessed. The viewing window 210-1 is labelled as “Source” since this viewing window 210-1 presents a default presentation of the native format of the acquired waveform, which may be considered the source data or a source file, which allows the user to visualize the data forming the acquired waveform. This default presentation of the native format of the acquired waveform is a time domain view of this waveform to allow the user to visualize the measurement data of the acquired waveform.

The user may then create new individual configurable viewing windows by selecting a create new view icon 212 in the display window 200. Each individual configurable viewing window created by selecting the new view icon shows up as a new tab at the top of the configurable viewing window 202. In the example of FIG. 2, the viewing window 210-1 is shown on the far left, a second individual configurable viewing window 210-2 created by the user is then shown to right of the tab for viewing window 210-1, and finally a third individual configurable viewing window 210-3 created by the user is then shown to right of tab for viewing window 210-2. Three viewing windows 210-1, 210-2, 210-3 are shown by way of example, with more or fewer being rendered in the display window depending on user inputs. Additional individual configurable viewing windows 210 may be created by the user as desired using the new view icon 212. The current or selected individual configurable viewing window 210-1, 210-2, 210-3 shown in the configurable viewing window 202 is chosen by selecting the tab corresponding to the desired one of the individual configurable viewing windows 210-1, 210-2, 210-3. The current individual configurable viewing window is illustrated by providing an indication in the tab for that viewing window. This selection indication is seen in the display window 200 where the tab for the individual configurable viewing window 210-3 is shaded, indicating the individual configurable viewing window 210-3 is the current or selected viewing window in the configurable viewing window 202.

Each of the individual configurable viewing windows 210-1, 210-2, 210-3 is individually configurable, meaning the user may insert in each of these configurable viewing windows 210-1, 210-2, 210-3 desired representations or transformations of the data forming the acquired waveform or frame F1-F3, LF in the timeline TL. Different frames F1-F3, LF may be selected for each individual configurable viewing window 210-1, 210-2, 210-3. In addition, within each individual configurable viewing window 210-1, 210-2, 210-3, a user may create or add one or more user-selectable feature views FV that display a desired data transformation for the selected acquired waveform. Each user-selectable feature view FV is positioned by the user at a desired location within the corresponding individual configurable viewing window 210-1, 210-2, 210-3. The user may also adjust the size of each user-selectable feature view FV so that all desired feature views may fit within the current individual configurable viewing window 210-1, 210-2, 210-3.

In the example of FIG. 2, the current individual configurable viewing window 210-3 includes three user-selectable feature view FV1-FV3 by way of example. Each feature view FV1-FV3 was created by the user by selecting an add feature icon 214 displayed in the individual configurable viewing window 210-3. The add feature icon 214 is selected by the user to create and configure all the desired feature views FV1-FV3 in the individual configurable viewing window 210-3. Thus, through the add feature icon 214, a user may visualize any of the desired data transformations for the one of the frames F1-F3, LF that is selected for the individual configurable viewing window 210-3. The user may customize each individual configurable viewing window 210-1, 210-2, 210-3 by selecting any of the data transformation to display information about the selected frame F1-F3, LF being analyzed.

The user utilizes the user-selectable feature views to perform desired types of data transformations on the data of the selected one of the frames F1-F3, LF to present characteristics of the data of the selected one of the frames F1-F3, LF that facilitate the testing or analysis of the DUT 124 (FIG. 1) being performed. In the example of FIG. 2, the individual configurable viewing window 210-3 includes the first feature view FV1, which provides a visual representation of the native format of the selected frame F1-F3, LF. A second feature view FV2 illustrates channels of data that are contained in the acquired waveform or frame F1-F3, LF from the instrument 102. The feature view FV2 may be referred to as a channel display that shows selected channels of the instrument 102 contained in the acquired waveform. In the illustrated example, six data channels C1-C6 are contained in the frames F1-F3, LF. These six data channels C1-C6 2 are also seen in the first feature view FV1 where the six channels C1-C6 are shown for the visual representation of the native format of the selected frame F1-F3, LF. Selected ones of the channels C1-C6 may be deselected by the user by clicking on the corresponding icon displayed for the channel in the feature view FV2. If a channel C1-C6 is deselected, the data for that channel is no longer displayed in feature views. For example, if the channel C3 is deselected in feature view FV2, then the signal or data for the channel C3 is removed from feature view FV1. A third feature view FV3 illustrates, by way of example, I2C decoding of the acquired waveform or frame F1-F3, LF, where I2C is a serial communication bus protocol for communicating between processors and microcontrollers and lower-speed peripheral integrated circuits.

In the example of FIG. 2 and the other example embodiments described herein, the measured data being acquired by the instrument 102 corresponds to signals being communicated on an I2C serial bus according to the I2C serial communication bus protocol. Embodiments of the disclosure are not, however, limited to the I2C serial communications bus protocol. In some embodiments, the measured data acquired by the instrument 102 is signals being communicated on other types of electrical buses according to other protocol standards, such as universal serial bus (USB) signals, controller area network (CAN) signals, serial peripheral interface (SPI) signals, as well as signals for other types of protocols that may be acquired and decoded by the instrument 102.

The user-selectable feature views may be utilized to perform many different types of types of data transformations on the measurement data of the selected one of the frames F1-F3, LF. Where the instrument 102 is an oscilloscope, for example, the feature views that may be configured by a user include automated tasks like performing protocol decode of signals contained in the acquired waveforms for different signal protocols and the generation of data eye diagrams for such signals. A feature view providing protocol decode for signals in the acquired waveform provide a protocol decode view of the selected acquired waveform, enabling a user to analyze the signals in the acquired waveform to determine whether these signals have been properly decoded. Other automated tasks capable of being performed by the instrument 102 may also be utilized by the user when configuring feature views to illustrate desired data transformations of the measurement data from the instrument 102. Measurement data from multiple instruments 102 may also be acquired in some embodiments, and desired feature views configured desired data transforms on measurement data from each of the multiple instruments.

To configure the feature views FV1-FV3 in the individual configurable viewing window 210-3, a user selects the add feature icon 214, which opens an additional window or windows (not shown in FIG. 2). The additional window or windows present fields or selections that enable the user to configure the feature view FV being created. The creation of the configured feature view FV includes selecting the desired data transformation for the feature view FV, as well as including the configuration of various parameters associated with the desired data transformation. Numerous different data transformations may be provided by the cloud-based platform 106 and made available for use in feature views FV that are created within an individual configurable viewing window 210. A user selects the data transformation that best enables the user to perform desired analysis of the selected frame F1-F3, LF, and the data transformation varies for different users analyzing the acquired waveforms of frames. For example, an RF engineer may be interested in frequency components of signals contained in the acquired waveforms while a software engineer may be interested in the I2C decoding of signals contained in the acquired waveforms. Data transformations that may be performed by the cloud-based platform 106 in accordance with embodiments of the disclosure are described in the previously incorporated U.S. Patent Application Publication Nos. 2022/0252647A1 and 2022/0163566A1 referred to above. The cloud-based platform 106 may perform additional data transformations in embodiments of the disclosure.

Finally, the display window 200 further includes notification and sharing options that may be configured by a user. More specifically, in the embodiment of FIG. 2 the display 200 includes a notification icon 216 in the upper right corner. Selecting the notification icon 216 opens a further window or windows (not shown in FIG. 2) that present fields or selections enabling the user to configure the notifications as desired. Notifications may, for example, be configured so that specific users receive notifications whenever a newly acquired waveform or frame F is added to the timeline TL. Such notifications improve collaboration for users interested in the testing of the DUT 124 (FIG. 1) by making desired users aware that a new frame F has been acquired for review and analysis by the user.

Sharing of individual configurable viewing windows 210 with selected users is accomplished through a sharing icon 218 in the upper right corner of the display window 200. Upon selecting the sharing icon 218, one or more windows (not shown in FIG. 2) open and present fields or otherwise enable the user to identify users with which the desired individual configurable viewing window 210 is to be shared. Once the desired users for sharing have been identified, a notification, such as an email or a text message, is sent to each user with whom the individual configurable viewing window 210 has been shared. Each user with which the desired individual configurable viewing window 210 has shared may thereafter view the viewing window on a corresponding remote user device 108A-N. Each such user may also add or modify feature views FV withing the shared individual configurable sharing window 210.

Finally, the display 200 includes a download icon 220 in the upper right corner. A user may select the download icon 220 to download to his or her remote user device 108A-N a selected frame F on the timeline TL. The user may have a local program or programs running on the remote user device 108A-N for analyzing a frame F on the timeline TL. The download icon 220 enables the user to download a desired frame or frames F to the remote user device 108A-N and thereafter utilize the local program to perform further analysis on the frame.

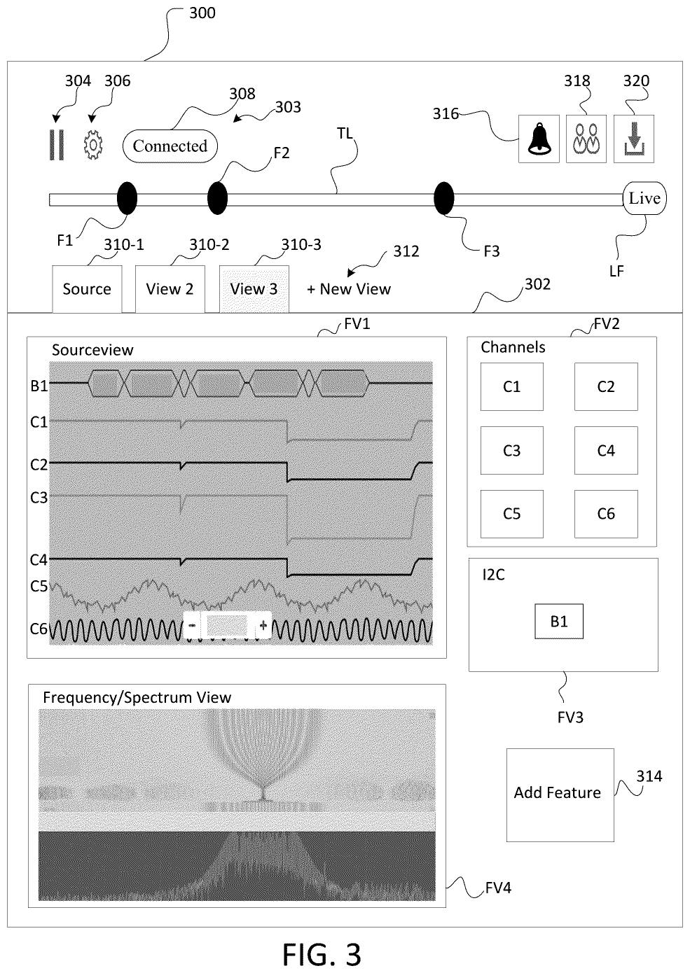

FIG. 3 is another example of a display window 300 rendered by one of the user interfaces 110A-N of FIG. 1 in accordance with embodiments of the disclosure. The display window 300 is similar to the display window 200 of FIG. 2 except the display window 300 includes a configurable viewing window 302 including an additional user-selectable feature view or view FV4 showing a frequency or spectrum view of the selected acquired waveform. The spectrum view of the selected acquired waveform in the feature view FV4 is a frequency domain representation of the selected acquired waveform. Feature views FV1-FV3 are the same as feature views FV1-FV3 in the configurable viewing window 202 of FIG. 2 except that the feature view FV1 in FIG. 3 has been resized to accommodate the inclusion of the additional feature view FV4 in the configurable viewing window 302. The display window 300 illustrates how the configurable viewing window 302 may be easily modified to add, or remove, desired user-selectable feature views FV. These modifications may be made by the original user that generated and shared the particular configurable viewing window 302, as well as by other users with whom the configurable viewing window 302 has been shared. The display window 300 in the example embodiment of FIG. 3 further includes components 304-320 that are the same as corresponding components 204-220 previously described with reference to the display window 200 of FIG. 2. As a result, these components 304-320 a not again be described in detail for the display window 300 of FIG. 3.

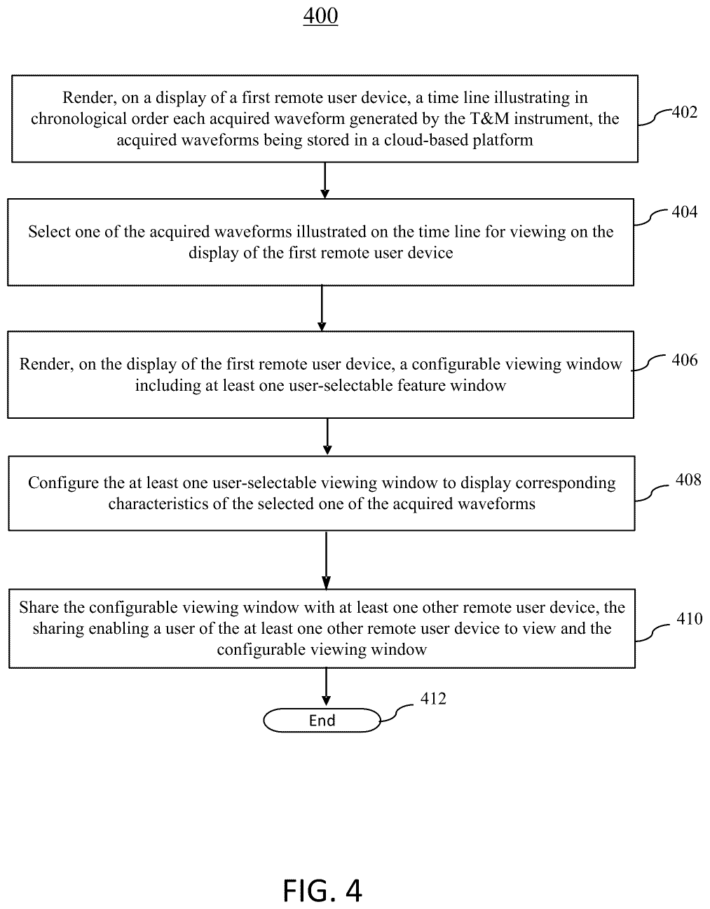

FIG. 4 is a flowchart illustrating example operations of a display process 400 executed through the presentation layer 112N and user interface 110N user interface of FIG. 2 in accordance with embodiments of the disclosure. The process 400 is now be described with reference to FIG. 4 as well as FIG. 1. The process 400 begins with operation 402, in which the presentation layer 112A-N on a first one of the remote user devices 108A-N renders, on a display 144 of the first remote user device, a timeline TL illustrating in chronological order each acquired waveform generated by the instrument 102. The acquired waveforms are stored in the cloud-based platform 106. From operation 402, the process 400 goes to operation 404 and a user provides input causing the presentation layer 112A-N to select one of the acquired waveforms or frames F1-F3, LF illustrated on the timeline TL for viewing on the display 144 of the first remote user device 108A-N. The process 400 then proceeds to operation 406 and the presentation layer 112A-N renders, on the display 144 of the first remote user device 108A-N, a configurable viewing window 202 including at least one user-selectable feature view FV. From operation 406 the process 400 continues to operation 408 and the user, through inputs provided to the presentation layer 112A-N, configures the at least one user-selectable viewing window 202 to display corresponding characteristics of the selected one of the acquired waveforms or frames F1-F3, LF. After operation 408, the process 400 advances to operation 410 and the user, through the sharing icon 218 in the configurable viewing window 202, supplies inputs to share the configurable viewing window with at least one other remote user device 108A-N. This sharing enables a user of the at least one other remote user device 108A-N to view the configurable viewing window 202. The process 400 then proceeds to operation 412 and ends.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may include computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a method of providing access to acquired waveforms from a test and measurement instrument including storing acquired waveforms from the test and measurement instrument in a cloud-based platform; rendering, on a first remote user device, a timeline illustrating in chronological order each acquired waveform from the test and measurement instrument in response to the acquired waveform being stored in the cloud-based platform; selecting, on the first remote user device, one of the acquired waveforms illustrated on the timeline for viewing on the first remote user device; rendering, on the first remote user device, a configurable viewing window including at least one user-selectable feature view; configuring, on the first remote user device, the at least one user-selectable feature view to display corresponding characteristics of the selected one of the acquired waveforms; receiving, on the first remote user device, a file from the cloud-based platform, the file including data for the at least one user-selectable feature view configured on the first remote user device; rendering, on the first remote user device, the configurable viewing window including the at least one user-selectable feature view using the file received from the cloud-based platform, the rendered at least one user-selectable feature view showing the corresponding characteristics of the selected one of the acquired waveforms; and sharing, in response to user input on the first remote user device, the configurable viewing window with at least one other remote user device, the sharing enabling a user of the at least one other remote user device to view the configurable viewing window.

Example 2 is a method according to Example 1, in which the method further includes configuring, on the at least one other remote user device, an additional configurable viewing window including at least one user-selectable feature view to display corresponding characteristics of a selected one of the acquired waveforms; and sharing, in response to user input on the at least one other remote user device, the additional configurable viewing window with the first remote user device.

Example 3 is a method according to Example 1, in which the file from the cloud-based platform includes data for a desired data transformation of measurement data from the test and measurement instrument for the selected one of the acquired waveforms.

Example 4 is a method according to Example 3, in which each of the at least one user-selectable feature views rendered in the configurable viewing window is one of a time domain view of the selected one of the acquired waveforms in native format, a zoomed view of the selected one of the acquired waveforms, a channel display showing selected channels of the test and measurement instrument contained in the selected one of the acquired waveforms that are selected for viewing, a frequency domain representation of the selected one of the acquired waveforms, and a protocol decode view of the selected one of the acquired waveforms.

Example 5 is a method according to Example 1, in which the timeline includes a plurality of icons, each of the acquired waveforms generated by the test and measurement instrument corresponding to one of the plurality of icons on the timeline.

Example 6 is a method according to Example 1, in which sharing the configurable viewing window with at least one other remote user device includes rendering, on the first remote user device, a sharing icon; selecting, in response to user input on the first remote user device, the sharing icon; identifying, in response to user input on the first remote user device, other remote user devices with which the configurable viewing window is to be shared; and sharing the configurable viewing window with the other remote user devices.

Example 7 is a method according to Example 1 further including rendering, on the first remote user device, a notification icon; selecting, in response to user input on the first remote user device, the notification icon; and configuring, in response to user input on the first remote user device, notifications to be received by the first remote user device in response to a newly acquired waveforms being generated by the test and measurement instrument and stored in the cloud-based platform.

Example 8 is a method according to Example 1 further including rendering, on the first remote user device, an instrument control panel; and controlling, on the first remote user device, operation of the test and measurement instrument through the instrument control panel.

Example 9 is a method according to Example 8, in which rendering the instrument control panel includes rendering, on the first remote user device, a pause icon as part of the instrument control panel, the pause icon, when selected in response to user input, causing the test and measurement instrument to pause acquiring additional acquired waveforms; and rendering, on the first remote user device, a configuration icon which, when selected in response to user input, enables a user to configure operational parameters of the test and measurement instrument.

Example 10 is a test and measurement system including a test and measurement instrument configured to generate acquired waveforms of one or more signals of device under test; a cloud-based platform coupled to the test and measurement instrument, the cloud-based platform configured to store acquired waveforms generated by the test and measurement instrument; and a plurality of remote user devices, each of the plurality of remote user devices including one or more processors configured to execute instructions to cause the processors to render a user interface on a display of the remote user device, the user interface including a presentation layer to display a timeline illustrating in chronological order each acquired waveform from the test and measurement instrument in response to the acquired waveform being stored in the cloud-based platform; and receive user input to select one of the acquired waveforms illustrated on the timeline for viewing on the display of the remote user device.

Example 11 is the test and measurement system of Example 10, in which the one or more processors are further configured to execute instructions to cause the presentation layer to display a plurality of configurable viewing windows, each configurable viewing window including at least one user-selectable feature view to display corresponding characteristics of the selected acquired waveform.

Example 12 is the test and measurement system of Example 11, in which the one or more processors are further configured to execute instructions to cause the presentation layer to display, within each configurable viewing window, an add features icon enabling a user to add a new user-selectable feature view to the configurable viewing window.

Example 13 is the test and measurement system of Example 11, in which each of the at least one user-selectable feature view displayed in each of the plurality of configurable viewing windows displays one of a time domain view of the selected acquired waveform in native format, a zoomed view of the selected acquired waveform, a channel display showing selected channels of the test and measurement instrument contained in the selected one of the acquired waveforms that are selected for viewing, a frequency domain representation of the selected acquired waveform, and a protocol decode view of the selected acquired waveform.

Example 14 is the test and measurement system of Example 10, in which the one or more processors are further configured to execute instructions to cause the presentation layer to receive user input to select one of the configurable viewing windows to be shared with other ones of the plurality of remote user devices; and share the selected one of the configurable viewing windows with the other ones of the plurality of remote user devices to enable users of the other ones of the plurality of remote user devices to view the selected one of the configurable viewing windows.

Example 15 is the test and measurement system of Example 10, in which the one or more processors are further configured to execute instructions to cause the presentation layer to render, on the display of the corresponding remote user device, a sharing icon; receive user input to select the sharing icon; receive user input to identify users of other ones of the plurality of remote user devices with which the selected one of the configurable viewing windows is to be shared; and share, in response to user input identifying the other ones of the plurality of remote user devices, the selected one of the configurable viewing windows.

Example 16 is the test and measurement system of Example 10, in which the cloud-based platform is further configured to store the acquired waveforms generated by the test and measurement instrument in native format.

Example 17 is the test and measurement system of Example 16, in which the cloud-based platform is further configured to at least one of compressed versions of each of the acquired waveforms generated by the test and measurement instrument and segmented versions of the acquired waveforms generated by the test and measurement instrument.

Example 18 is the test and measurement system of Example 11, in which the test and measurement instrument is an oscilloscope.

Example 19 is a remote user device including a memory and one or more processors configured to render, on a display of a first remote user device, a timeline illustrating in chronological order each acquired waveform generated by a test and measurement instrument, each acquired waveform being stored in a cloud-based platform; select one of the acquired waveforms illustrated on the timeline for viewing on the display of the first remote user device; render, on the display of the first remote user device, a configurable viewing window including at least one user-selectable feature view; configure the at least one user-selectable viewing window to display corresponding characteristics of the selected one of the acquired waveforms; and share the configurable viewing window with at least one other remote user device, the sharing enabling a user of the at least one other remote user device to view the configurable viewing window.

Example 20 is the remote user device of Example 19, in which the one or more processors are further configured to add, to the timeline, icons representing each acquired waveform generated by the test and measurement instrument as these acquired waveforms are stored in the cloud-based platform.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A method of providing access to acquired waveforms from a test and measurement instrument, comprising:
storing acquired waveforms from the test and measurement instrument in a cloud-based platform;
rendering, on a first remote user device, a timeline illustrating in chronological order each acquired waveform from the test and measurement instrument in response to the acquired waveform being stored in the cloud-based platform;
selecting, on the first remote user device, one of the acquired waveforms illustrated on the timeline for viewing on the first remote user device;
rendering, on the first remote user device, a configurable viewing window including at least one user-selectable feature view;
configuring, on the first remote user device, the at least one user-selectable feature view to display corresponding characteristics of the selected one of the acquired waveforms;
receiving, on the first remote user device, a file from the cloud-based platform, the file including data for the at least one user-selectable feature view configured on the first remote user device;
rendering, on the first remote user device, the configurable viewing window including the at least one user-selectable feature view using the file received from the cloud-based platform, the rendered at least one user-selectable feature view showing the corresponding characteristics of the selected one of the acquired waveforms; and
sharing, in response to user input on the first remote user device, the configurable viewing window with at least one other remote user device, the sharing enabling a user of the at least one other remote user device to view the configurable viewing window.

2. The method of claim 1 further comprising:
configuring, on the at least one other remote user device, an additional configurable viewing window including at least one user-selectable feature view to display corresponding characteristics of a selected one of the acquired waveforms; and
sharing, in response to user input on the at least one other remote user device, the additional configurable viewing window with the first remote user device.

3. The method of claim 1, wherein the file from the cloud-based platform comprises data for a desired data transformation of measurement data from the test and measurement instrument for the selected one of the acquired waveforms.

4. The method of claim 3, wherein each of the at least one user-selectable feature views rendered in the configurable viewing window is one of a time domain view of the selected one of the acquired waveforms in native format, a zoomed view of the selected one of the acquired waveforms, a channel display showing selected channels of the test and measurement instrument contained in the selected one of the acquired waveforms that are selected for viewing, a frequency domain representation of the selected one of the acquired waveforms, and a protocol decode view of the selected one of the acquired waveforms.

5. The method of claim 1, wherein the timeline includes a plurality of icons, each of the acquired waveforms generated by the test and measurement instrument corresponding to one of the plurality of icons on the timeline.

6. The method of claim 1, wherein sharing the configurable viewing window with at least one other remote user device comprises:
rendering, on the first remote user device, a sharing icon;
selecting, in response to user input on the first remote user device, the sharing icon;
identifying, in response to user input on the first remote user device, other remote user devices with which the configurable viewing window is to be shared; and
sharing the configurable viewing window with the other remote user devices.

7. The method of claim 1 further comprising:
rendering, on the first remote user device, a notification icon;
selecting, in response to user input on the first remote user device, the notification icon; and
configuring, in response to user input on the first remote user device, notifications to be received by the first remote user device in response to a newly acquired waveforms being generated by the test and measurement instrument and stored in the cloud-based platform.

8. The method of claim 1, further comprising:
rendering, on the first remote user device, an instrument control panel; and
controlling, on the first remote user device, operation of the test and measurement instrument through the instrument control panel.

9. The method of claim 8, wherein rendering the instrument control panel comprises:
rendering, on the first remote user device, a pause icon as part of the instrument control panel, the pause icon, when selected in response to user input, causing the test and measurement instrument to pause acquiring additional acquired waveforms; and
rendering, on the first remote user device, a configuration icon which, when selected in response to user input, enables a user to configure operational parameters of the test and measurement instrument.

10. A test and measurement system, comprising:
a test and measurement instrument configured to generate acquired waveforms of one or more signals of device under test;
a cloud-based platform coupled to the test and measurement instrument, the cloud-based platform configured to store acquired waveforms generated by the test and measurement instrument; and
a plurality of remote user devices, each of the plurality of remote user devices including one or more processors configured to execute instructions to cause the processors to render a user interface on a display of the remote user device, the user interface including a presentation layer to:
display a timeline illustrating in chronological order each acquired waveform from the test and measurement instrument in response to the acquired waveform being stored in the cloud-based platform; and
receive user input to select one of the acquired waveforms illustrated on the timeline for viewing on the display of the remote user device.

11. The test and measurement system of claim 10, wherein the one or more processors are further configured to execute instructions to cause the presentation layer to:
display a plurality of configurable viewing windows, each configurable viewing window including at least one user-selectable feature view to display corresponding characteristics of the selected acquired waveform.

12. The test and measurement system of claim 11, wherein the one or more processors are further configured to execute instructions to cause the presentation layer to:
display, within each configurable viewing window, an add features icon enabling a user to add a new user-selectable feature view to the configurable viewing window.

13. The test and measurement system of claim 11, wherein each of the at least one user-selectable feature view displayed in each of the plurality of configurable viewing windows displays one of a time domain view of the selected acquired waveform in native format, a zoomed view of the selected acquired waveform, a channel display showing selected channels of the test and measurement instrument contained in the selected one of the acquired waveforms that are selected for viewing, a frequency domain representation of the selected acquired waveform, and a protocol decode view of the selected acquired waveform.

14. The test and measurement system of claim 10, wherein the one or more processors are further configured to execute instructions to cause the presentation layer to:
receive user input to select one of the configurable viewing windows to be shared with other ones of the plurality of remote user devices; and
share the selected one of the configurable viewing windows with the other ones of the plurality of remote user devices to enable users of the other ones of the plurality of remote user devices to view the selected one of the configurable viewing windows.

15. The test and measurement system of claim 10, wherein the one or more processors are further configured to execute instructions to cause the presentation layer to:
render, on the display of the corresponding remote user device, a sharing icon;
receive user input to select the sharing icon;
receive user input to identify users of other ones of the plurality of remote user devices with which the selected one of the configurable viewing windows is to be shared; and
share, in response to user input identifying the other ones of the plurality of remote user devices, the selected one of the configurable viewing windows.

16. The test and measurement system of claim 10, wherein the cloud-based platform is further configured to store the acquired waveforms generated by the test and measurement instrument in native format.

17. The test and measurement system of claim 16, wherein the cloud-based platform is further configured to at least one of compressed versions of each of the acquired waveforms generated by the test and measurement instrument and segmented versions of the acquired waveforms generated by the test and measurement instrument.

18. The test and measurement system of claim 11, wherein the test and measurement instrument comprises an oscilloscope.

19. A remote user device, comprising:
a memory; and
one or more processors configured to:
render, on a display of a first remote user device, a timeline illustrating in chronological order each acquired waveform generated by a test and measurement instrument, each acquired waveform being stored in a cloud-based platform;
select one of the acquired waveforms illustrated on the timeline for viewing on the display of the first remote user device;
render, on the display of the first remote user device, a configurable viewing window including at least one user-selectable feature view;
configure the at least one user-selectable viewing window to display corresponding characteristics of the selected one of the acquired waveforms; and
share the configurable viewing window with at least one other remote user device, the sharing enabling a user of the at least one other remote user device to view the configurable viewing window.

20. The remote user device of claim 19, wherein the one or more processors are further configured to add, to the timeline, icons representing each acquired waveform generated by the test and measurement instrument as these acquired waveforms are stored in the cloud-based platform.
